(19) United States
(12) Patent Application Publication
(10) Pub. No.: US 2017/0309455 A1
(43) Pub. Date: Oct. 26, 2017

(54) PLASMA APPARATUS

(71) Applicant: TOYOTA JIDOSHA KABUSHIKI KAISHA, Toyota-shi (JP)

(72) Inventors: Takuya YOSHIMURA, Miyoshi-shi (JP); Masafumi KOIZUMI, Nagoya-shi (JP); Kotaro IDE, Nisshin-shi (JP); Yu ASHITAKA, Kariya-shi (JP)

(73) Assignee: TOYOTA JIDOSHA KABUSHIKI KAISHA, Toyota-shi, (JP)

(21) Appl. No.: 15/491,350

(22) Filed: Apr. 19, 2017

(30) Foreign Application Priority Data
Apr. 25, 2016 (JP) 2016-086809
Jun. 13, 2016 (JP) 2016-116778

(51) Int. Cl. H01J 37/32; C23C 16/50; H05H 1/46

(52) U.S. Cl. CPC H01J 37/32174; H05H 1/46; C23C 16/50; H01J 2237/334; H05H 2001/4682

(57) ABSTRACT

A plasma apparatus configured to form a film on or etch a work piece includes: a vacuum chamber including a first casing that has a first recess and a first flat part disposed around the first recess, and a second casing disposed opposite to the first casing; an insulating member that is disposed between the first flat part of the first casing and the second casing, and is configured to contact with the work piece in a state where the work piece faces a space inside the first recess and is separated from the first flat part; and an electricity application unit that is configured to apply electricity to the work piece, wherein a distance between the first flat part and a contact point between the work piece and the insulating member is shorter than a distance between the work piece and a bottom part of the first recess.

### INCORPORATION BY REFERENCE

The disclosure of Japanese Patent Application No. 2016-086809 filed on Apr. 25, 2016 and Japanese Patent Application No. 2016-116778 filed on Jun. 13, 2017, each including the specification, drawings and abstract, is incorporated herein by reference in its entirety.

### BACKGROUND

### 1. Technical Field

The present disclosure relates to a plasma apparatus.

### 2. Description of Related Art

Apparatuses for forming a film on a substrate by the plasma chemical vapor deposition (CVD) method are known. Japanese Patent Application Publication No. 2013-206652 describes an apparatus that is provided with a holder for holding a substrate inside a vacuum chamber, and forms a film by applying a bias voltage from a bias power source to the holder. In this apparatus, the vacuum chamber and the bias power source are insulated from each other by an insulating member.

### SUMMARY

In the apparatus described in JP 2013-206652 A, as the electric field concentrates in an area of contact between the insulating member and a voltage line leading from the bias power source to the holder, entry of plasma into this area can result in abnormal electric discharge. Such abnormal electric discharge can also occur when the apparatus performs etching by the plasma CVD method. Thus, there has been a demand for a technique that can suppress such abnormal electric discharge in an apparatus that forms films or performs etching by the plasma CVD method.

The present disclosure provides a plasma apparatus in which abnormal electric discharge is suppressed.

According to one aspect of the present disclosure, there is provided a plasma apparatus that is configured to form a film on or etch a portion of a work piece by the plasma chemical vapor deposition method. This plasma apparatus includes: a vacuum chamber including a first casing that has a first recess and a first flat part disposed around the first recess, and a second casing that is disposed opposite to the first casing; an insulating member that is disposed between the first flat part of the first casing and the second casing, and comes in contact with the work piece in a state where a portion to be treated of the work piece faces a space inside the first recess and the work piece is separated from the first flat part; and an electricity application unit that applies electricity to the work piece, wherein the distance between the first flat part and a contact point between the work piece and the insulating member is shorter than the distance between the work piece and a bottom part of the first recess. According to this plasma apparatus, the insulating member coming in contact with the work piece is disposed between the first flat part and the second casing, and the distance between the first flat part and the contact point between the work piece and the insulating member is shorter than the distance between the work piece and the bottom part of the first recess. Thus, entry of plasma from the first recess into a space formed by the work piece and the first flat part is suppressed. Accordingly, the amount of plasma at the contact point between the work piece and the insulating member is reduced, so that abnormal electric discharge can be suppressed.

According to the above mentioned aspect of the disclosure, a distance along the first flat part from a junction between the first recess and the first flat part to the contact point may be larger than zero.

In the plasma apparatus of the above aspect of the disclosure, the distance between the first flat part and the contact point may be shorter than the distance of a sheath formed between the work piece and the first flat part. According to this plasma apparatus, the distance between the first flat part and the contact point between the work piece and the insulating member is shorter than the distance of the sheath formed between the work piece and the first flat part. Thus, generation of plasma between the work piece and the first flat part can be prevented. Accordingly, the amount of plasma at the contact point is effectively reduced, so that abnormal electric discharge can be effectively suppressed.

In the plasma apparatus of the above aspect of the disclosure, the distance between the first flat part and the contact point may be 2.0 mm or less. According to this plasma apparatus, entry of plasma from the first recess into the space formed by the work piece and the first flat part is further suppressed. Moreover, generation of plasma between the work piece and the first flat part can be prevented. Accordingly, the amount of plasma at the contact point is further reduced, so that abnormal electric discharge can be further suppressed.

In the plasma apparatus of the above aspect of the disclosure, the work piece may include an object to be treated, and a masking member covering a portion not to be treated of the object to be treated; and a junction between the first recess and the first flat part may be located so as to be separated from an end of the portion to be treated toward the insulating member. To form a film on or etch the portion to be treated by generating plasma in the space between the work piece and the vacuum chamber to which electricity is applied, it is preferable that the portion to be treated and the vacuum chamber be separated from each other by a distance longer than the distance of the so-called sheath. As plasma is not generated in an area where the portion to be treated and the vacuum chamber are close to each other, film formation failure or etching failure may occur at the end of the portion to be treated. According to the plasma apparatus of the above configuration, however, the junction between the first recess and the first flat part of the vacuum chamber is located so as to be separated from the end of the portion to be treated of the object to be treated toward the insulating member. Thus, the distance between the portion to be treated and the vacuum chamber can be secured. Accordingly, film formation failure or etching failure at the end of the portion to be treated can be prevented.

In the plasma apparatus of the above aspect of the disclosure, an end of the masking member on the side closer to the portion to be treated may have an inclined surface inclined toward the first recess. According to the plasma apparatus of this configuration, concentration of the electric field at the end of the masking member on the side closer to the portion to be treated can be suppressed, so that a decrease in film formation density or etching density at the end of the portion to be treated can be prevented.

In the plasma apparatus of the above aspect of the disclosure, an angle formed between the inclined surface and a contact surface of the masking member may be 30° or less. The contact surface is configured to contact with the object to be treated. According to the plasma apparatus of this configuration, concentration of the electric field at the end of the masking member on the side closer to the portion to be treated can be further suppressed, so that a decrease in film formation density or etching density at the end of the portion to be treated can be further prevented.

In the plasma apparatus of the above aspect of the disclosure, the plasma apparatus may further include a first electrode disposed inside the first recess, a second electrode disposed inside the second recess, and a high-frequency electricity application unit that is configured to apply high-frequency electricity to the first electrode and the second electrode; the second casing may have a second recess and a second flat part disposed around the second recess; and the work piece may be configured to separate a space inside the first recess and a space inside the second recess from each other. According to the plasma apparatus of this configuration, the space inside the first recess and the space inside the second recess are separated from each other by the work piece, and these spaces are electrically insulated from each other. Thus, phase interference between high frequency applied to the first electrode and high frequency applied to the second electrode is prevented, so that electricity applied can be efficiently used to form a film on or etch the work piece.

The present disclosure can also be realized in various forms other than the form of the above-described plasma apparatus. For example, the present disclosure can be realized in the forms of a method for forming a film on or etching a portion of a work piece by the plasma CVD method; of a control method and a control device for a plasma apparatus; of a computer program for realizing the functions of such method and device; and of a recording medium storing this computer program.

### BRIEF DESCRIPTION OF THE DRAWINGS

Features, advantages, and technical and industrial significance of exemplary embodiments of the disclosure will be described below with reference to the accompanying drawings, in which like numerals denote like elements, and wherein:

FIG. 1 is a schematic sectional view showing a configuration of a plasma apparatus in a first embodiment of the present disclosure;

FIG. 2 is an exploded perspective view of the plasma apparatus;

FIG. 3 is an enlarged partial view of the plasma apparatus;

FIG. 4 is a flowchart showing a plasma treatment method performed with the plasma apparatus;

FIG. 5 is a view showing a plasma apparatus in Modified Example 1 of the first embodiment;

FIG. 6 is a view showing a plasma apparatus in Modified Example 2 of the first embodiment;

FIG. 7 is a view showing a plasma apparatus in Modified Example 3 of the first embodiment;

FIG. 8 is a view showing a plasma apparatus in Modified Example 4 of the first embodiment;

FIG. 9 is a view showing a plasma apparatus in Modified Example 6 of the first embodiment;

FIG. 10 is a schematic partial sectional view showing a part of a configuration of a plasma apparatus in a second embodiment;

FIG. 11 is a schematic partial sectional view showing a part of a configuration of a plasma apparatus in a third embodiment;

FIG. 12 is a view showing results of an experiment on an angle D;

FIG. 13 is a view showing a relation between the angle D and a contact resistance value;

FIG. 14 is a schematic partial sectional view showing a part of a configuration of a plasma apparatus in Modified Example 1 of the third embodiment;

FIG. 15 is a schematic partial sectional view showing a part of a configuration of a plasma apparatus in Modified Example 2 of the third embodiment;

FIG. 16 is a view showing a plasma apparatus in a fourth embodiment; and

FIG. 17 is a flowchart showing a plasma treatment method in a modified example of the fourth embodiment.

### DETAILED DESCRIPTION OF EMBODIMENTS

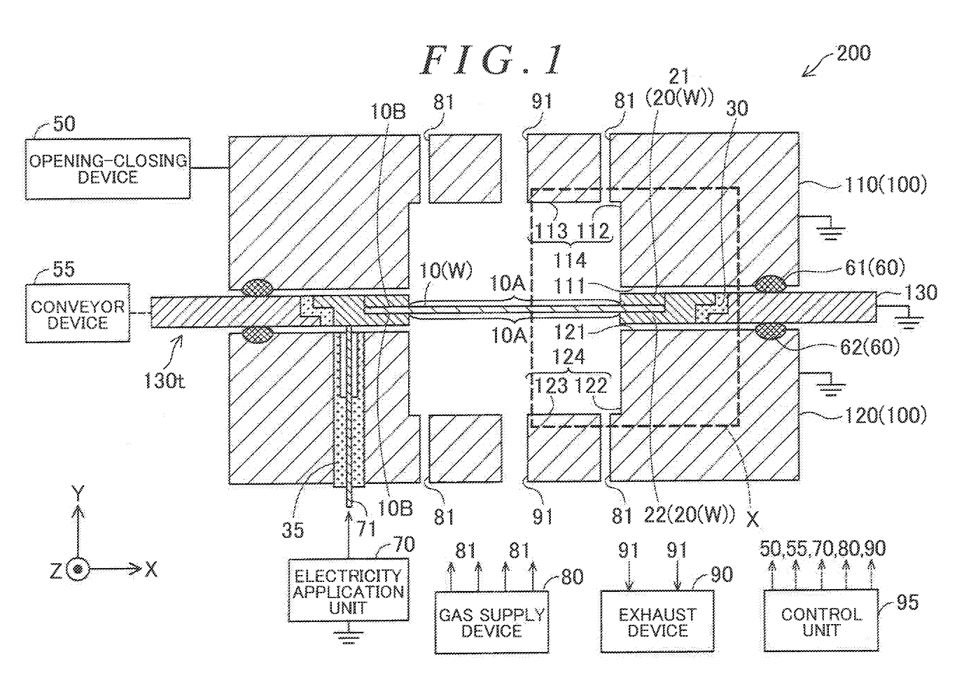

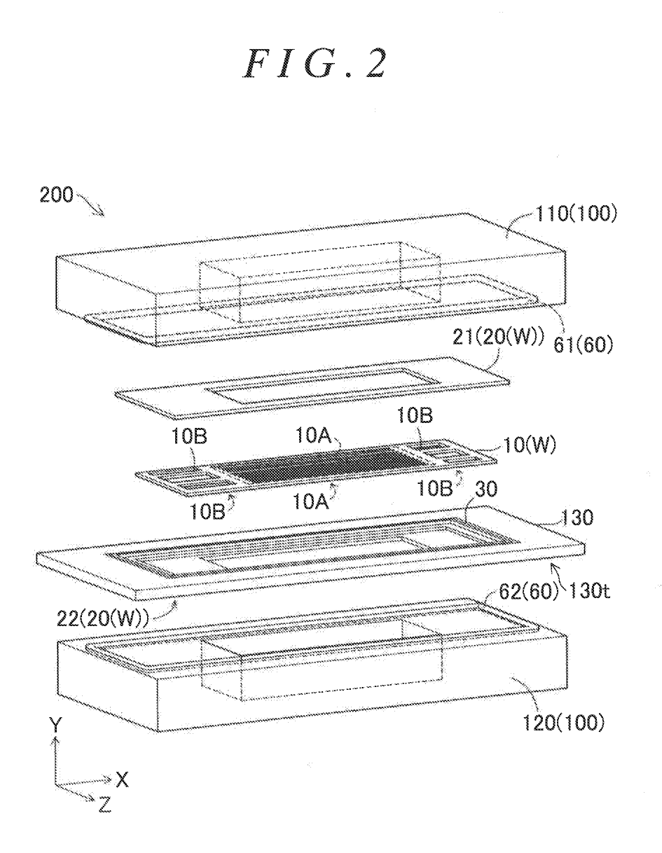

FIG. 1 is a schematic sectional view showing a configuration of a plasma apparatus 200 in a first embodiment of the present disclosure. FIG. 2 is an exploded perspective view of the plasma apparatus 200. In FIG. 1 and FIG. 2, X- Y- and Z-axes orthogonal to one another are indicated. A Y-axis direction represents a vertical direction; an X-axis direction represents a horizontal direction; and a Z-axis direction represents a direction perpendicular to the Y-axis and the X-axis. The same applies to the subsequent drawings.

The plasma apparatus 200 is an apparatus that forms thin films on portions to be treated 10A of a conductive work piece W by the so-called plasma chemical vapor deposition (CVD) method. In this embodiment, the work piece W includes an object to be treated 10 and a masking member 20. In this embodiment, the object to be treated 10 is a metal plate used as a substrate for a separator of a fuel cell. For example, the plasma apparatus 200 forms conductive carbon-based thin films on the portions to be treated 10A of the object to be treated 10.

The plasma apparatus 200 includes a vacuum chamber 100, an insulating member 30, and an electricity application unit 70. The plasma apparatus 200 further includes an opening-closing device 50, a conveyor device 55, a gas supply device 80, an exhaust device 90, a control unit 95, a pallet 130, and a seal member 60. In FIG. 2, the opening-closing device 50, the conveyor device 55, the electricity application unit 70 and an electricity introduction part 71 thereof, the gas supply device 80 and supply ports 81 thereof, the exhaust device 90 and exhaust ports 91, and the control unit 95 are not shown.

The vacuum chamber 100 is a splittable metal chamber. The vacuum chamber 100 includes a first casing 110 and a second casing 120 disposed opposite to the first casing 110. The first casing 110 has a first recess 114 and a first flat part 111 disposed around the first recess 114. The first recess 114 is recessed in a direction away from the work piece W, and in this embodiment, the first recess 114 is recessed upward (in a +Y-axis direction) as seen from the portion to be treated 10A on an upper surface side of the work piece W The first recess 114 has a side part 112 and a bottom part 113. The first flat part 111 extends from the side part 112 of the first recess 114. In this embodiment, a junction between the first recess 114 and the first flat part 111 is located in the same YZ plane as an end of the portion to be treated 10A. The second casing 120 has a second recess 124 that is recessed downward (in a −Y-axis direction) as seen from the portion to be treated 10A on a lower surface side of the work piece W, and a second flat part 121 that is disposed around the second recess 124. The second recess 124 has a side part 122 and a bottom part 123. The second flat part 121 is disposed in an area corresponding to the first flat part 111 of the first casing 110. In this embodiment, a junction between the second recess 124 and the second flat part 121 is located in the same YZ plane as an end of the portion to be treated 10A. In this embodiment, the first flat part 111 and the second flat part 121 are parallel to the XZ plane. The first casing 110 and the second casing 120 each include the supply ports 81 through which a gas is supplied from the gas supply device 80 into the vacuum chamber 100, and the exhaust port 91 through which a gas is exhausted from the vacuum chamber 100 by the exhaust device 90. The supply ports 81 and the exhaust ports 91 are provided with valves that can open and close these ports. The second casing 120 includes the electricity introduction part 71 through which voltage is applied to the work piece W. The second casing 120 and the electricity introduction part 71 are electrically insulated from each other by an insulating member 35. In this embodiment, the vacuum chamber 100 has earth potential. Inside the vacuum chamber 100, the work piece w is separated from the first flat part 111, and the portion to be treated 10A of the work piece W faces a space inside the first recess 114 in a state where the vacuum chamber 100 is closed.

In this embodiment, a portion of the work piece W located inside the first recess 114 and the second recess 124 is not provided with a hole that penetrates the work piece W between the upper surface side and the lower surface side. However, the portion of the work piece W located inside the first recess 114 and the second recess 124 may he provided with a hole that penetrates the work piece W between the upper surface side and the lower surface side in a state where the vacuum chamber 100 is closed.

The masking member 20 is a member covering portions not to be treated 10B of the object to be treated 10. In other words, the masking member 20 is a Member that is open over the portion to be treated 10A of the object to be treated 10, in this embodiment, the masking member 20 includes an upper masking member 21 and a lower masking member 22. The upper masking member 21 is disposed on a side of the object to be treated 10 closer to the first casing 110. The lower masking member 22 is disposed on a side of the object to be treated 10 closer to the second casing 120. In this embodiment, the lower masking member 22 supports the object to be treated 10. The masking member 20 is formed by a conductive member. The object to be treated 10 and the masking member 20 are electrically connected by coming in contact with each other.

The insulating member 30 is disposed between the first flat part 111 of the first casing 110 and the second casing 120. In this embodiment, the insulating member 30 is disposed between the first flat part 111 and the second flat part 121. The insulating member 30 comes in contact with the work piece W in a state where the portion to be treated 10A on the upper surface side of the work piece W faces the space inside the first recess 114 and the work piece W is separated from the first flat part 111. In this embodiment, the insulating member 30 comes in contact with the work piece W in a state where the portion to be treated 10A on the lower surface side of the work piece W faces the space inside the second recess 124 and the work piece W is separated from the second flat part 121. In this embodiment, the insulating member 30 supports the lower masking member 22 of the work piece W by coming in contact with the lower masking member 22. For example, the insulating member 30 is made of ceramic, such as alumina (Al₂O₃) or silicon dioxide (SiO₂).

The pallet 130 is a plate-like metal member. The pallet 130 is a member used to convey the work piece W into the vacuum chamber 100. On the pallet 130, the insulating member 30, the lower masking member 22, the object to be treated 10, and the upper masking member 21 are loaded in this order in the +Y-axis direction. In this embodiment, the pallet 130 has earth potential.

The seal member 60 (61, 62) is disposed between the first flat part 111 of the first casing 110 and the second casing 120. The seal member 60 is a member that keeps the vacuum chamber 100 gastight. The seal member 60 is a member having an insulating property, and is an annular rubber member in this embodiment. O-rings are used as the seal member 60 in this embodiment. In this embodiment, the seal member 61 is fitted in a groove provided in the first casing 110. The seal member 62 is fitted in a groove provided in the second casing 120.

The opening-closing device 50 is a device that opens and closes the vacuum chamber 100. In this embodiment, the opening-closing device 50 opens the vacuum chamber 100 by moving the first casing 110 in the +Y-axis direction, and closes the vacuum chamber 100 by moving the first casing 110 in the −Y-axis direction.

The conveyor device 55 is a device that conveys the pallet 130 into the vacuum chamber 100 and conveys the pallet 130 out of the vacuum chamber 100. In this embodiment, the conveyor device 55 comes in contact with an end 130t of the pallet 130, and conveys the pallet 130 and the insulating member 30, the masking member 20, and the object to be treated 10 loaded on the pallet 130 into the vacuum chamber 100 in a state where the vacuum chamber 100 is open. The conveyor device 55 moves the conveyed pallet 130 downward to install the pallet 130 on the second casing 120 through the seal 25 member 62. The conveyor device 55 can also move the pallet 130 upward and then along the XZ plane to convey the pallet 130 out of the vacuum chamber 100.

The electricity application unit 70 is a device that generates plasma. The electricity application unit 70 applies electricity to the work piece W. The electricity application unit 70 creates an electric field where a source gas supplied into the vacuum chamber 100 is turned into plasma. In this embodiment, the electricity introduction part 71, the object to be treated 10, and the masking member 20 are cathodes, while the first casing 110, the second casing 120, and the pallet 130 are anodes. In this embodiment, the electricity application unit 70 applies a bias voltage to the object to be treated 10 through the lower masking member 22. For example, the electricity application unit 70 can apply a voltage of −3000V to the electricity introduction part 71. In this embodiment, the vacuum chamber 100 and the pallet 130 are connected to the earth (0V).

The gas supply device 80 supplies a carrier gas and a source gas into the vacuum chamber 100 through the supply ports 81. In this embodiment, the gas supply device 80 supplies, for example, a nitrogen (N₂) gas or an argon (Ar) gas as the carrier gas, and supplies, for example, a pyridine (C₅H₅N) gas as the source gas. The gas supply device 80 is connected to tanks storing different types of gases. The gas supply device 80 can switch the type of gas to be supplied to the supply ports 81 according to operation of a selector valve provided between each tank and the supply ports 81. To bring the pressure inside the vacuum chamber 100 back to such a pressure that the opening-closing device 50 can open the vacuum chamber 100, the gas supply device 80 supplies a nitrogen gas, for example, into the vacuum chamber 100 after film formation or etching by the plasma apparatus 200.

The exhaust device 90 exhausts a gas from the vacuum chamber 100 through the exhaust ports 91. For example, the exhaust device 90 is a rotary pump, diffusion pump, or turbo-molecular pump.

The control unit 95 controls operation of the entire plasma apparatus 200. The control unit 95 includes a CPU and a memory. The CPU controls the plasma apparatus 200 by executing a program stored in the memory. This program may be stored in any other type of recording medium. For example, the control unit 95 controls the opening-closing device 50 to open and close the vacuum chamber 100, and controls the conveyor device 55 to convey the pallet 130. Moreover, the control unit 95 controls the exhaust device 90 to exhaust a gas from the vacuum chamber 100, controls the gas supply device 80 to supply a gas into the vacuum chamber 100, and controls the electricity application unit 70 to apply electricity to the work piece W.

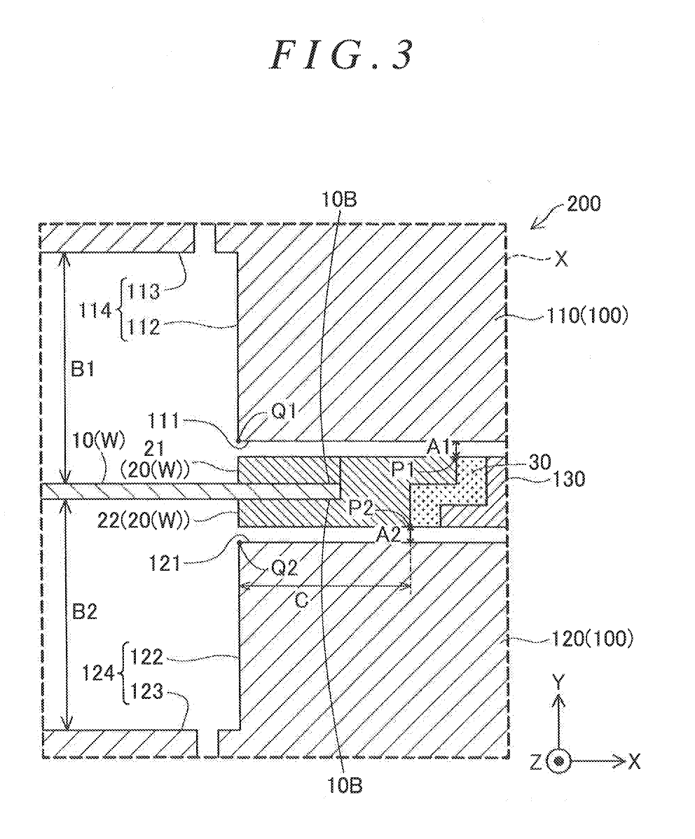

FIG. 3 is an enlarged partial view of the plasma apparatus 200. FIG. 3 shows a part X indicated by the dashed line in FIG. 1. In FIG. 3, a contact point P1 between the work piece W and the insulating member 30 and a contact point P2 between the work piece W and the insulating member 30 are indicated. Of areas of contact between the work piece W and the insulating member 30, the contact point P1 is located in an area of contact facing the first flat part 111. Of the areas of contact between the work piece W and the insulating member 30, the contact point P1 is located in the area of contact closest to the first flat part 111 in a cross-section of the plasma apparatus 200 (FIG. 3). Of the areas of contact between the work piece W and the insulating member 30, the contact point P2 is located in an area of contact facing the second flat part 121. Of the areas of contact between the work piece W and the insulating member 30, the contact point P2 is located in the area of contact closest to the second flat part 121 in the cross-section of the plasma apparatus 200 (FIG. 3). In FIG. 3, a distance A1 between the first flat part 111 and the contact point P1, and a distance 131 between the work piece W and the bottom part 113 of the first recess 114 are further indicated. The distance A1 is the shortest distance between the first flat part 111 and the area of contact between the work piece W and the insulating member 30. The distance 131 is a distance between the work piece W facing the first recess 114 and the bottom part 113 of the first recess 114, and is the shortest distance between the bottom part 113 of the first recess 114 and the work piece W. In FIG. 3, a distance A2 between the second flat part 121 and the contact point P2, and a distance B2 between the work piece W and the bottom part 123 of the second recess 124 are also indicated. The distance A2 is the shortest distance between the second flat part 121 and the area of contact between the work piece W and the insulating member 30. The distance B2 is a distance between the work piece W facing the second recess 124 and the bottom part 123 of the second recess 124, and is the shortest distance between the bottom part 123 of the second recess 12.4 and the work piece W. The distance A1 is shorter than the distance B1 in the plasma apparatus 200. In other words, a space formed by the work piece W and the first flat part 111 is smaller than a space formed by the work piece W and the first recess 114. In this embodiment, the distance A2 is shorter than the distance B2. In other words, a space formed by the work piece W and the second flat part 121 is smaller than a space formed by the work piece W and the second recess 124.

In this embodiment, the distance A1 and the distance A2 are shorter than a distance of a sheath that is formed between the work piece W and the vacuum chamber 100 (first flat part 111 and second flat part 121) when electricity is applied to the space between the work piece W and the vacuum chamber 100. In this embodiment, the distance A1 and the distance A2 are 2.0 mm or less. From the viewpoint of keeping the vacuum chamber 100 and the work piece W well insulated from each other, it is preferable that the distance A1 and the distance A2 be 0.5 mm or more.

In FIG. 3, a shortest distance C along the X-axis from a junction Q1 between the side part 112 of the first recess 114 and the first flat part 111 and a junction Q2 between the second recess 124 and the second flat part 121 respectively to the contact points P1, P2 is further indicated. The distance C is also the shortest distance along the X-axis from the side part 112 of the first recess 114 and the side part 122 of the second recess 124 respectively to the contact points P1, P2. In this embodiment, the distance C is larger than zero. In this embodiment, the distance C is 10 mm or more.

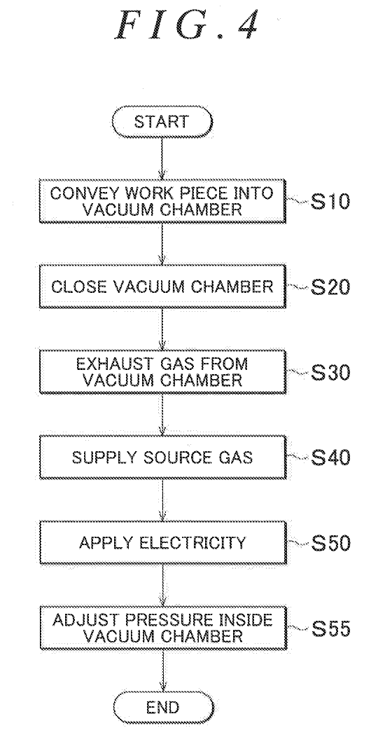

FIG. 4 is a flowchart showing a plasma treatment method performed with the plasma apparatus 200. A method of forming films on portions of the work piece W by the plasma apparatus 200 will be described below as an example. To form films by the plasma apparatus 200, first, the work piece W is conveyed into the vacuum chamber 100 (step S10). In this embodiment, the insulating member 30, the lower masking member 22, and the object to be treated 10 are loaded on the pallet 130, and the upper masking member 21 is further loaded on the object to be treated 10. Thus, the portions not to be treated 10B of the object to be treated 10 are covered by the masking member 20. Thereafter, the first casing 110 of the vacuum chamber 100 is moved in the +Y-axis direction by the opening-closing device 50, and the pallet 130 loaded with the insulating member 30, the masking member 20, and the object to be treated 10 is conveyed into the vacuum chamber 100 by the conveyor device 55. The conveyed pallet 130 is disposed on the second casing 120 through the seal member 62.

Next, the vacuum chamber 100 is closed (step S20). In this embodiment, after the pallet 130 is conveyed into the vacuum chamber 100, the first casing 110 is moved in the −Y-axis direction by the opening-closing device 50. When the vacuum chamber 100 is closed, the portions to be treated 10A respectively face the spaces inside the first recess 114 and the second recess 124 of the vacuum chamber 100. The work piece W is separated from the first flat part 111 and the second flat part 121. The distance A1 between the first flat part 111 and the contact point P1 is shorter than the distance B1 between the work piece W and the first recess 114. The distance A2 between the second flat part 121 and the contact point P2 is shorter than the distance B2 between the work piece W and the second recess 124.

Next, a gas is exhausted from the vacuum chamber 100 (step S30). In this embodiment, the plasma apparatus 200 is installed in a nitrogen gas atmosphere, for example. In step S30, the nitrogen gas is exhausted from the vacuum chamber 100 through the exhaust ports 91 by the exhaust device 90, to create a vacuum inside the vacuum chamber 100.

When the gas is exhausted from the vacuum chamber 100, a source gas is supplied into the vacuum chamber 100 (step S40). In step S40, a carrier gas and the source gas are supplied through the supply ports 81 by the gas supply device 80. For example, a hydrogen gas and an argon gas are supplied as the carrier gas into the vacuum chamber 100. A nitrogen gas and a pyridine gas are supplied as the source gas. In step S40, the value of the pressure inside the vacuum chamber 100 is 11 Pa, for example. To accelerate film formation, for example, the temperature of the work piece W may be raised by applying electricity to the space between the work piece W (object to be treated 10 and masking member 20) and the vacuum chamber 100 by the electricity application unit 70 before the source gas is supplied.

Next, electricity is applied to the work piece W (step S50). When electricity is applied to the space between the work piece W and the vacuum chamber 100 by the electricity application unit 70, plasma is generated inside the first recess 114 and the second recess 124, and thin films are formed on the portions to be treated 10A of the object to be treated 10. In this way, films are formed by the plasma apparatus 200. In step S50, for example, −3000V electricity is applied to the work piece W by the electricity application unit 70. Upon completion of step S50, supply of the source gas and application of electricity are stopped to complete film formation.

Upon completion of film formation, the pressure inside the vacuum chamber 100 is adjusted (step S55). In this embodiment, to bring the pressure inside the vacuum chamber 100 back to such a pressure that the opening-closing device 50 can open the vacuum chamber 100, a nitrogen gas is supplied into the vacuum chamber 100 by the gas supply device 80. When the pressure inside the vacuum chamber 100 has been adjusted, the first casing 110 is moved in the +Y-axis direction by the opening-closing device 50, and the pallet 130 loaded with the insulating member 30, the masking member 20, and the object to be treated 10 is conveyed out of the vacuum chamber 100 by the conveyor device 55. Thus, the sequence of steps of the plasma treatment method performed with the plasma apparatus 200 are completed.

According to the plasma apparatus 200 of the first embodiment, in a state where the vacuum chamber 100 is closed, the insulating member 30 coming in contact with the work piece W is disposed between the first flat part 111 of the first casing 110 and the second casing 120, and the distance A1 between the first flat part 111 and the contact point P1 between the work piece W and the insulating member 30 is shorter than the distance B1 between the work piece W and the bottom part 113 of the first recess 114. Thus, entry of plasma from the first recess 114 and the second recess 124 into the space formed by the work piece W and the first fat part 111 is suppressed. Accordingly, the amount of plasma at the contact point P1 is reduced, so that abnormal electric discharge can be suppressed.

Similarly, the distance A2 between the second flat part 121 and the contact point P2 between the work piece W and the insulating member 30 is shorter than the distance B2 between the work piece W and the bottom part 123 of the second recess 124. Thus, entry of plasma from the second recess 124 and the first recess 114 into the space formed by the work piece W and the second flat part 121 is suppressed. Accordingly, the amount of plasma at the contact point P2 is reduced, so that abnormal electric discharge can be suppressed.

The distance C along the X-axis from the junction Q1 between the first recess 114 and the first flat part 111 and the junction Q2 between the second recess 124 and the second flat part 121 to the insulating member 30 is larger than zero. Thus, the space formed by the first recess 114 and the second recess 124 where plasma is generated and the contact points P1, P2 between the work piece W and the insulating member 30 are separated from each other. Accordingly, the amount of plasma at the contact points P1, P2 is further reduced, so that abnormal electric discharge can be further suppressed.

As the distance A1 between the first flat part 111 and the contact point P1 between the work piece W and the insulating member 30 is shorter than the distance of the sheath formed between the work piece W and the first flat part 111, generation of plasma between the work piece W and the first flat part 111 can be prevented. Similarly, as the distance A2 between the second flat part 121 and the contact point P2 between the work piece W and the insulating member 30 is shorter than the distance of the sheath formed between the work piece W and the second flat part 121, generation of plasma between the work piece W and the second flat part 121 can be prevented. Accordingly, the amount of plasma at the contact points P1, P2 is effectively reduced, so that abnormal electric discharge can be effectively suppressed.

As the distance A1 and the distance A2 is 2.0 mm or less, entry of plasma from the first recess 114 and the second recess 124 into the space formed by the work piece W and the first flat part 111 and the space formed by the work piece W and the second flat part 121 is further suppressed. Moreover, generation of plasma between the work piece V and the first flat part 111 can be prevented. Generation of plasma between the work piece W and the second flat part 121 can also be prevented. Accordingly, the amount of plasma at the contact points P1, P2 is further reduced, so that abnormal electric discharge can be further suppressed.

In the plasma apparatus 200, the portions to be treated 10A of the work piece W respectively face the space inside the first recess 114 and the space inside the second recess 124, and the insulating member 30 and ends of the work piece W are located between the first flat part. 111 and the second flat part 121. Thus, the plasma apparatus 200 can be reduced in size compared with if the work piece W is entirely housed inside the space where plasma is generated. Moreover, as the space from which a gas is exhausted for film formation or etching is small, the plasma apparatus 200 requires less time to exhaust a gas, and thus requires less time to form a film on or etch the work piece W.

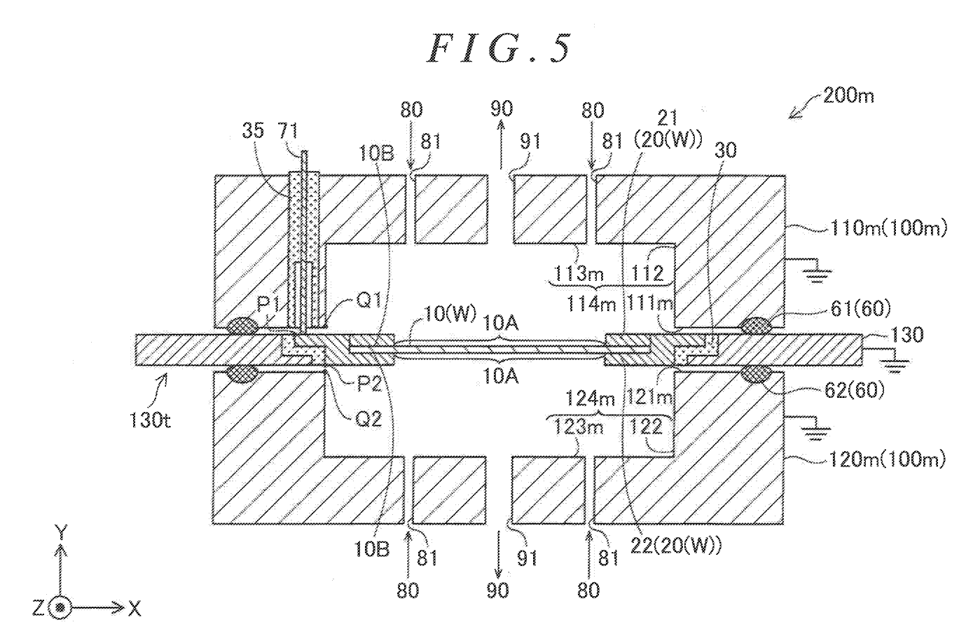

FIG. 5 is a view showing a plasma apparatus 200m in Modified Example 1 of the first embodiment. In FIG. 5 and the subsequent drawings, the opening-closing device 50, the conveyor device 55, the electricity application unit 70, the gas supply device 80, the exhaust device 90, and the control unit 95 are not shown. In the plasma apparatus 200m of this modified example, the shortest distance along a first flat part 111m from the junction Q1 between a first recess 114m and the first flat part 111m and the junction Q2 between a second recess 124m and a second flat part 121m respectively to the contact points P1, P2 between the work piece W and the insulating member 30 is zero. In this modified example, the junction Q2 and the contact point P2 are located in the same YZ plane. Accordingly, as shown in FIG. 5, in a vacuum chamber 100m, the upper masking member 21 is exposed to the first recess 114m of a first casing 110m, and a portion of the lower masking member 22 is exposed to the second recess 124m of a second casing 120m, In this modified example, as in the first embodiment, a distance between the first flat part 111m and the contact point P1 is shorter than a distance between the work piece W and a bottom part 113m of the first recess 114m. Similarly, a distance between the second flat part 121m and the contact point P2 is shorter than a distance between the work piece W and a bottom part 123m of the second recess 124m. Abnormal electric discharge can also be suppressed in the plasma apparatus 200m as in the first embodiment.

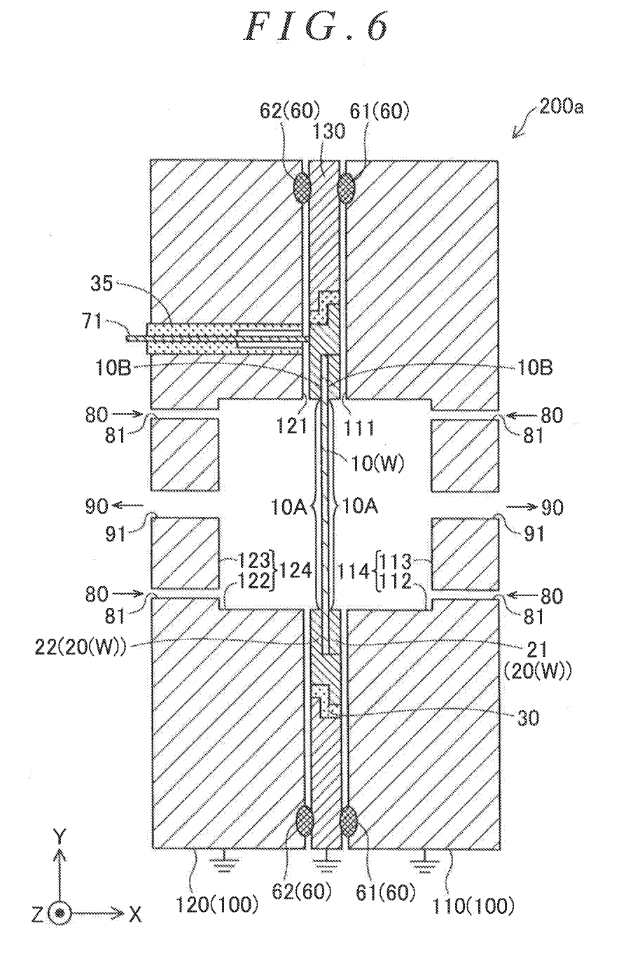

FIG. 6 is view showing a plasma apparatus 200a in Modified Example 2 of the first embodiment. The plasma apparatus 200a of this modified example has the configuration of the plasma apparatus 200 of the first embodiment turned 90° in the X-axis direction. In this modified example, the vacuum chamber 100 is opened and closed in the X-axis direction. In this modified example, it is preferable that the insulating member 30, the masking member 20, and the pallet 130 be fitted together with such a coupling force that these components will not fall. Or, it is preferable that the insulating member 30, the masking member 20, and the pallet 130 be each fastened with bolts, etc. Abnormal electric discharge can also be suppressed in the plasma apparatus 200a as in the first embodiment.

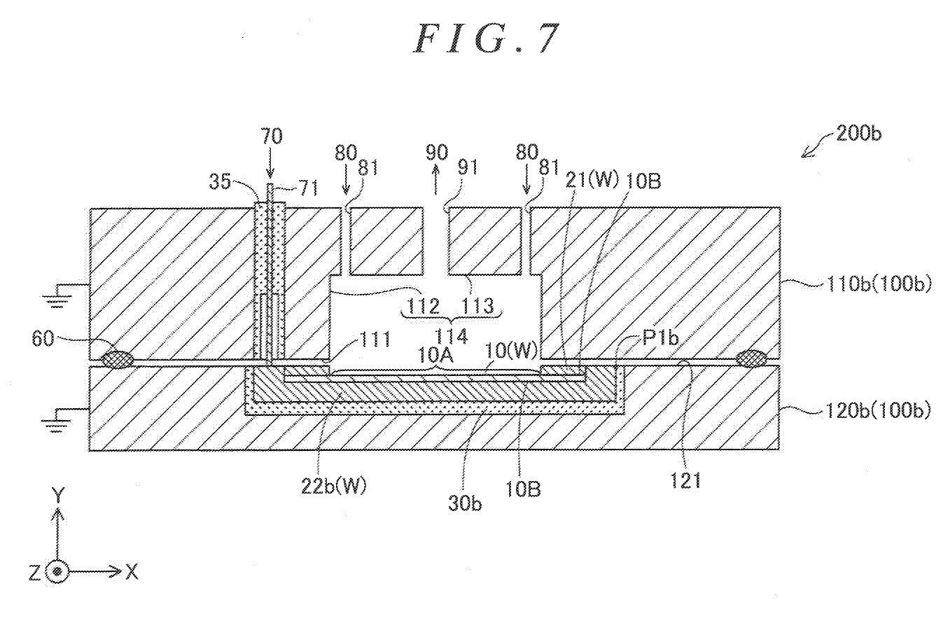

FIG. 7 shows a plasma apparatus 200b in Modified Example 3 of the first embodiment. Unlike the plasma apparatus 200 of the first embodiment, the plasma apparatus 200b forms a film on or etches only one side of the object to be treated 10 that is closer to the first recess 114. Accordingly, in this modified example, with no space left between a second easing 120b of a vacuum chamber 100b and the object to be treated 10, an insulating member 30b is in contact with an upper side of the second casing 120b, a lower masking member 22b is in contact with an upper side of the insulating member 30b, and the entire lower side of the object to be treated 10 is in contact with an upper side of the lower masking member 22b. In this modified example, the plasma apparatus 200b does not include the pallet 130. In this modified example, the electricity introduction part 71 is provided on the side of the first casing 110b. As in the first embodiment, a distance between the first flat part 111 and a contact point P1b between the work piece W and the insulating member 30b is shorter than a distance between the work piece W and the bottom part 113 of the first recess 114. Abnormal electric discharge can also be suppressed in the plasma apparatus 200b as in the first embodiment.

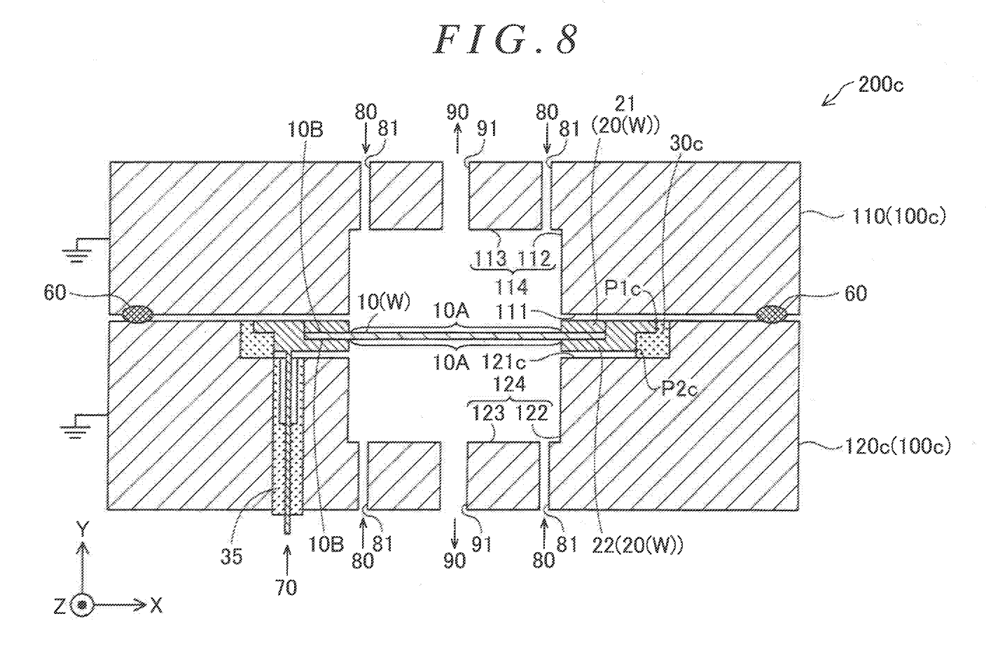

FIG. 8 is a view showing a plasma apparatus 200c in Modified Example 4 of the first embodiment. The plasma apparatus 200c of this modified example is different from the plasma apparatus 200 of the first embodiment mainly in that the work piece W is disposed without using the pallet 130. In this modified example, therefore, the work piece W and a second casing 120c are separated from each other in a vacuum chamber 100c while a second flat part 121c of the second casing 120c is in contact with an insulating member 30c. In this modified example, as in the first embodiment, a distance between the first flat part 111 and a contact point P1c between the work piece W and the insulating member 30c is shorter than a distance between the work piece W and the bottom part 113 of the first recess 114. Similarly, a distance between the second flat part 121c and a contact point P1c between the work piece W and the insulating member 30c is shorter than a distance between the work piece W and the bottom part 123 of the second recess 124. The rest of the configuration of this modified example is the same as in the first embodiment. Abnormal electric discharge can also be suppressed in the plasma apparatus 200c as in the first embodiment.

In the first embodiment, films are formed on the portions of the work piece W by the plasma apparatus 200. Alternatively, in Modified Example 5 of the first embodiment, portions of the work piece W may be etched by the plasma apparatus 200. In the case of etching, for example, a gas mainly containing argon may be supplied into the vacuum chamber 100 in the step of supplying a gas (step S40 in FIG. 4) of the above-described plasma treatment.

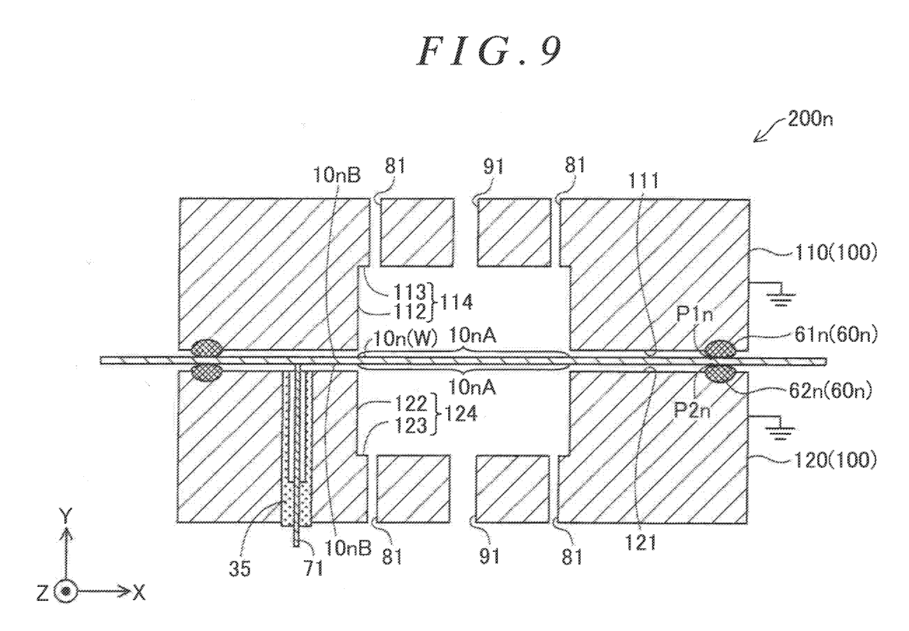

FIG. 9 is a view showing a plasma apparatus 200n in Modified Example 6 of the first embodiment. In the plasma apparatus 200n, the pallet 130 and the insulating member 30 are not used, and the work piece W (object to be treated 10n) is conveyed into the vacuum chamber 100 by the conveyor device 55. In the plasma apparatus 200n, instead of the insulating member 30 of the above embodiment, a seal member 60n having an insulating property comes in contact with the work piece W in a state where a portion to be treated 10nA on the upper surface side of the work piece W faces the space inside the first recess 114 and the work piece W is separated from the first flat part 111. The seal member 61n is in contact with the first flat part 111 of the first casing 110 and portions not to be treated 10nB of the object to be treated 10n. A seal member 62n is in contact with the second flat part 121 of the second casing 120 and portions not to be treated 10nB. In FIG. 9, a contact point P1n between the work piece W and the seal member 60n and a contact point P2n between the work piece W and the seal member 60n are indicated. As in the first embodiment, a distance between the first flat part 111 and the contact point P1n is shorter than a distance between the work piece W and the bottom part 113 of the first recess 114. Similarly, a distance between the second flat part 121 and the contact point P2n is shorter than a distance between the work piece W and the bottom part 123 of the second recess 124. Abnormal electric discharge can also be suppressed in the plasma apparatus 200n as in the above embodiment. In this modified example, the work piece W may be composed of the object to be treated 10n and the masking member 20.

In the first embodiment, the plasma apparatus 200 may include an electrode that can apply high-frequency electricity to at least one of the first recess 114 and the second recess 124, and a high-frequency electricity application unit that applies high-frequency electricity to the electrode. According to this configuration, as the density of plasma generated inside the first recess or the second recess can be increased by high frequency applied to the electrode, it is possible to enhance the film formation density or the etching density, as well as to increase the film thickness or the amount of etching. Moreover, abnormal electric discharge can also be suppressed as in the first embodiment.

In the first embodiment, the distance A1 between the first flat part 111 and the contact point P1 is shorter than the distance of the sheath formed between the work piece W and the first flat part 111, and the distance A2 between the second flat part 121 and the contact point P2 is shorter than the distance of the sheath formed between the work piece W and the second flat part 121. Alternatively, either the distance A1 or the distance A2 may be longer than the distance of the sheath, or both the distance A1 and the distance A2 may be longer than the distance of the sheath. In the first embodiment, the distance A1 and the distance A2 are 2.0 mm or less. Alternatively, either the distance A1 or the distance A2 may be more than 2.0 mm, or both the distance A1 and the distance A2 may be more than 2.0 mm.

In the first embodiment, the work piece W includes the object to be treated 10 and the masking member 20, but the masking member 20 may be omitted from the work piece W.

In the first embodiment, the first recess 114 has the side part 112 and the bottom part 113, but the first recess 114 may have another shape, for example, a hemispherical shape, provided that the first recess 114 is recessed from the first flat part 111 in a direction away from the object to be treated 10. In this case, the bottom part 113 of the first recess 114 may be an area that is farthest away from the work piece W facing the first recess 114, and the distance B1 between the work piece W and the bottom part 113 of the first recess 114 may be a distance between the work piece W facing the first recess 114 and the area of the first recess 114 farthest away from the work piece W.

In the first embodiment, the vacuum chamber 100 and the pallet 130 have earth potential, but the potential of the vacuum chamber 100 and the pallet 130 is not limited to earth potential. A minimum requirement for the electricity application unit 70 is to be able to apply electricity for forming a film on or etching the object to be treated 10 to the space between the vacuum chamber 100 and the object to be treated 10.

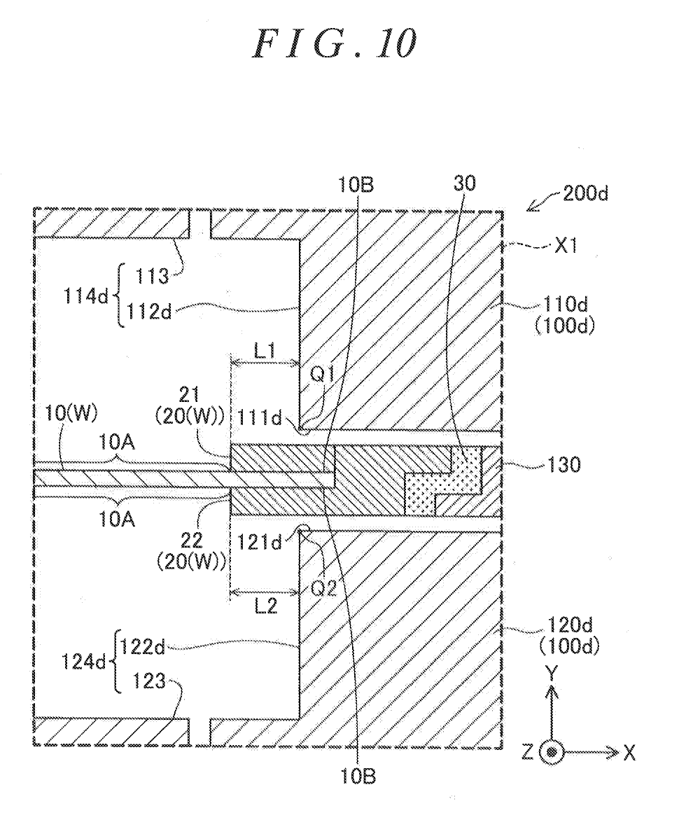

FIG. 10 is a schematic partial sectional view showing a part of a configuration of a plasma apparatus 200d in a second embodiment. FIG. 10 shows a part X1 corresponding to the part X of FIG. 1. In the plasma apparatus 200d of this embodiment, the junction Q1 between a first recess 114d (side part 112d) and a first flat part 111d of a first casing 110d is located so as to be separated from the end of the portion to be treated 10A toward the insulating member 30. Similarly, the junction Q2 between a second recess 124d (side part 122d) and a second flat part 121d of a second casing 120d is located so as to be separated from the end of the portion to be treated 10A toward the insulating member 30.

In FIG. 10, a distance L1 along the X-axis from the junction Q1 between the first recess 114d and the first flat part 111d to the end of the portion to be treated 10A is indicated. A distance L2 along the X-axis from the junction Q2 between the second recess 124d and the second flat part 121d to the end of the portion to be treated 10A is also indicated. In this embodiment, the distance L1 and the distance L2 are equal. For example, if the electricity applied to the work piece W by the electricity application unit 70 is −1000V and the pressure inside a vacuum chamber 100d is 10 Pa, the distances L1, L2 are preferably about 3 mm or more. For example, if the electricity applied to the work piece W by the electricity application unit 70 is −3000V and the pressure inside the vacuum chamber 100d is 10 Pa, the distances L1, L2 are preferably about 9 mm or more. Thus, the distances L1, L2 can be changed according to the electricity applied by the electricity application unit 70 and the pressure (degree of vacuum) inside the vacuum chamber 100d. Description of the rest of the configuration of the plasma apparatus 200d of this embodiment, which is the same as in the plasma apparatus 200 of the first embodiment, will be omitted.

To form a film on or etch the portion to be treated 10A by generating plasma in the space between the work piece W and the vacuum chamber 100d to which electricity is applied, it is preferable that the portion to be treated 10A and the vacuum chamber 100d be separated from each other by a distance longer than the distance of the so-called sheath. As plasma is not generated in an area where the portion to be treated 10A and the vacuum chamber 100d are close to each other, film formation failure or etching failure may occur at the end of the portion to be treated 10A. According to the plasma apparatus 200d of this embodiment, however, the junction Q1 between the first recess 114d and the first flat part 111d of the vacuum chamber 100d is located so as to be separated from the end of the portion to be treated 10A on the upper surface side of the work piece W toward the insulating member 30. Thus, the distance between the portion to be treated 10A and the vacuum chamber 100d can be secured. Accordingly, film formation failure or etching failure at the end of the portion to be treated 10A on the upper surface side of the work piece W can be prevented.

Similarly, the junction Q2 between the second recess 124d and the second flat part 121d of the vacuum chamber 100d is located so as to be separated from the end of the portion to be treated 10A on the lower surface side of the work piece W toward the insulating member 30. Thus, the distance between the portion to be treated 10A on the lower surface side of the work piece W and the vacuum chamber 100d can be secured. Accordingly, film formation failure or etching failure at the end of the portion to be treated 10A on the lower surface side of the work piece W can be prevented.

As the configuration of the plasma apparatus 200d of this embodiment is similar to that of the first embodiment, abnormal electric discharge can also be suppressed in the plasma apparatus 200d as in the first embodiment.

In the second embodiment, the distance L1 from the junction Q1 between the first recess 114d and the first flat part 111d to the end of the portion to be treated 10A, and the distance L2 from the junction Q2 between the second recess 124d and the second flat part 121d to the end of the portion to be treated 10A are equal. Alternatively, the distance L1 and the distance L2 may be different. For example, only the junction Q1 between the first recess 114d and the first flat part 111d may be located so as to he separated from the end of the portion to be treated 10A on the upper surface side of the work piece W toward the insulating member 30, or only the junction Q2 between the second recess 124d and the second flat part 121d may be located so as to be separated from the end of the portion to be treated 10A on the lower surface side of the work piece W toward the insulating member 30.

The same modifications as shown in Modified Examples 1 to 8, 10, and 11 of the first embodiment can be made to the plasma apparatus 200d of the second embodiment.

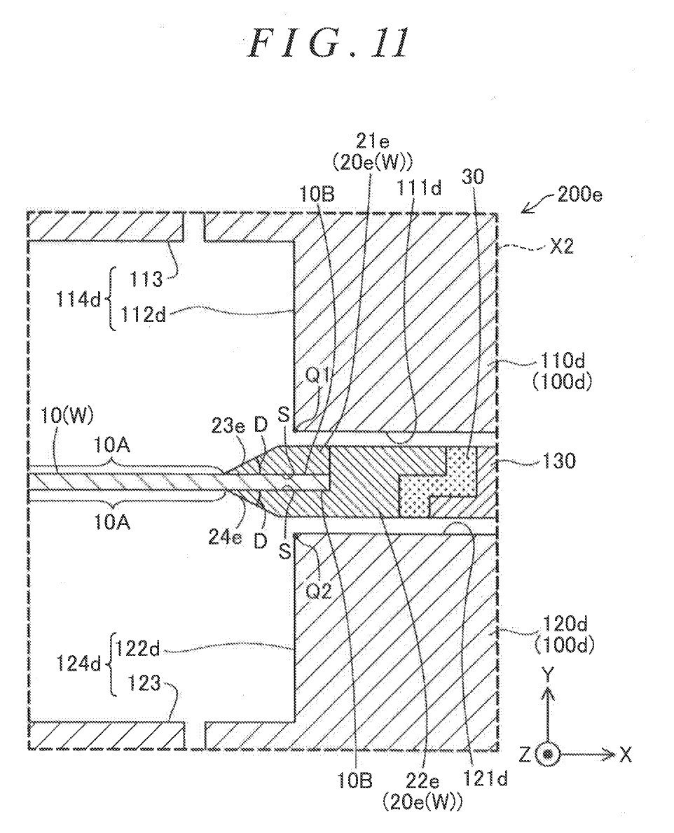

FIG. 11 is a schematic partial sectional view showing a part of a configuration of a plasma apparatus 200e in a third embodiment. FIG. 11 shows a part X2 corresponding to the part X of FIG. 1. The plasma apparatus 200e of this embodiment is different from the plasma apparatus 200 of the first embodiment in that a masking member 20e (21e, 22e) has inclined surfaces 23e, 24e. Specifically, an end of the upper masking member 21e on a side closer to the portion to be treated 10A has the inclined surface 23e inclined toward the first recess 114d. Similarly, an end of the lower masking member 22e on a side closer to the portion to be treated 10A has the inclined surface 24e inclined toward the second recess 124d. The inclined surfaces 23e, 24e are surfaces that are inclined relative to a contact surface S of the masking member 20e (21e, 22e) in contact with the portion not to be treated 10B. In this embodiment, the inclined surfaces 23e, 24e are in contact with the ends of the portions to be treated 10A.

In this embodiment, as in the second embodiment, the junction Q1 between the first recess 141d and the first flat part 111d and the junction Q2 between the second recess 124d and the second flat part 121d are located so as to be separated from the ends of the portions to be treated 10A toward the insulating member 30. Description of the rest of the configuration of the plasma apparatus 200e of this embodiment, which is the same as in the plasma apparatus 200d of the second embodiment, will be omitted.

According to the plasma apparatus 200e of this embodiment, the upper masking member 21e in contact with the portion to be treated 10A has the inclined surface 23e inclined toward the first recess 114d, which can suppress concentration of the electric field at the end of the upper masking member 21e. Thus, a decrease in film formation density or etching density at the end of the portion to be treated 10A on the upper surface side of the work piece W can be prevented. Similarly, the lower masking member 22e has the inclined surface 24e inclined toward the second recess 124d, which can suppress concentration of the electric field at the end of the lower masking member 22e. Thus, a decrease in film formation density or etching density at the end of the portion to be treated 10A on the lower surface side of the work piece W can be prevented.

From the viewpoint of further preventing a decrease in film formation density or etching density at the ends of the portions to be treated 10A, it is preferable that angles D formed between the inclined surfaces 23e, 24e and the contact surfaces S be 30° or less.

Reasons why it is preferable that the angles D formed between the inclined surfaces 23e, 24eand the contact surfaces S be 30° or less will be described below on the basis of results of an experiment.

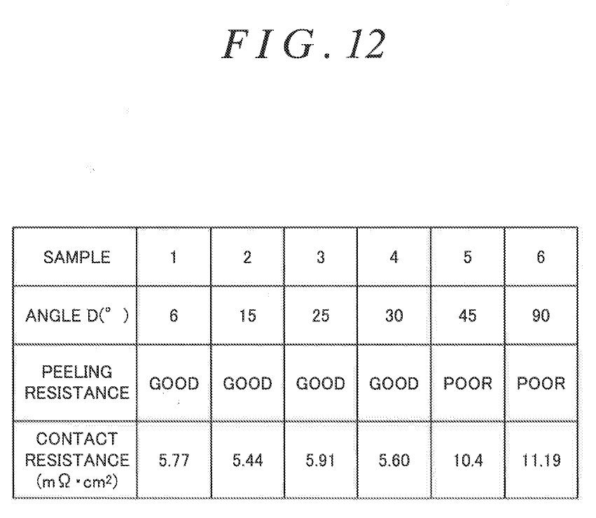

FIG. 12 is a view showing the results of the experiment on the angle D. In this experiment, six types of masking members with different angles D of 6°, 15°, 25°, 30°, 45°, and 90° were prepared. The masking member with the angle D of 90° did not have the inclined surface, and the end thereof in contact with the portion to be treated 10A had a rectangular shape. Next, using these masking members, films were formed on the objects to be treated 10 by the plasma apparatus 200e to produce Samples 1 to 6. The films were formed by the same method as in the first embodiment, using the same film formation conditions (the type of gas, gas flow rate, amount of electricity, etc.) for Samples 1 to 6. Next, an acceleration test was conducted by leaving the samples in a pressure cooker at a temperature from 120° C. to 140° C. for about an hour. Thereafter, the surface condition of each sample was observed to evaluate whether the film was peeled at the end of the portion to be treated 10A. Those samples in which no peeling was observed were evaluated as ‘good’ in peeling resistance, while those samples in which peeling was observed were evaluated as ‘poor’ in peeling resistance. It can be said that, in those samples in which no peeling was observed, unevenness of film formation was suppressed and the film had a sufficient density at the end of the portion to be treated 10A. After the acceleration test, the value of the contact resistance near the end of the portion to be treated 10A of each sample was measured by the four terminal method. It can be said that, in those samples with a low contact resistance value, too, the film had a sufficient density at the end of the portion to be treated 10A. FIG. 12 shows whether the film was peeled in each sample and the contact resistance value thereof.

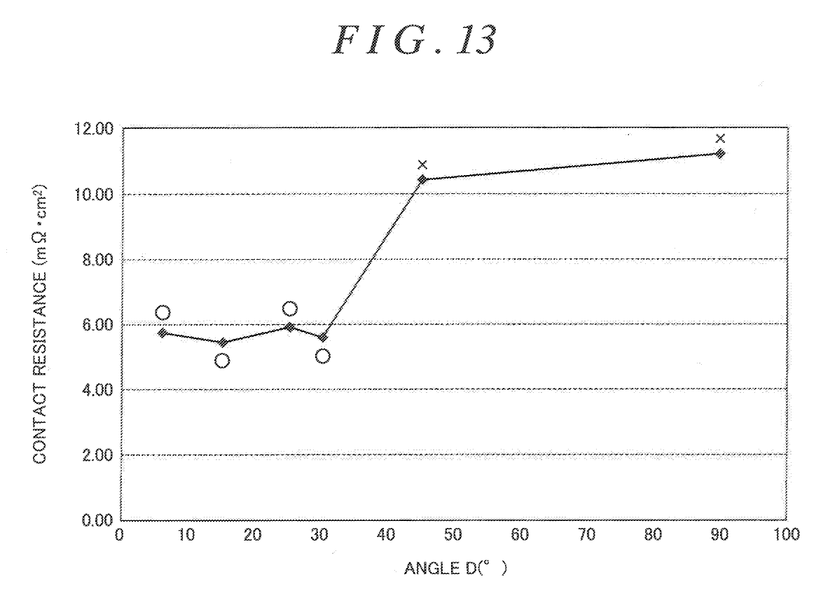

FIG. 13 is a view showing a relation between the angle D and the contact resistance value. In FIG. 13, whether the film was peeled in each sample is also indicated by a circle-mark and a cross-mark. The circle indicates no file peeling was observed, and the cross indicates film peeling was observed, in a sample. As shown in FIG. 12 and FIG. 13, in Sample 5 with the angle D of 45°, film peeling was observed and the contact resistance value was 10.4 (mΩ·cm²). In Sample 6 with the angle D of 90°, film peeling was observed and the contact resistance value was 11.19 (mΩ·cm²), which was higher than that of Sample 5. By contrast, in Samples 1 to 4 with the angles D respectively of 6°, 15°, 25°, and 30°, no film peeling was observed and the contact resistance values were 5.44 to 5.91 (mΩ·cm²), which were significantly lower than those of Samples 5 and 6. These results demonstrate the following. Firstly, if the angle D is 30° or less, unevenness of film formation is further suppressed and the film has a sufficient density at the end of the portion to be treated 10A. Secondly, according to the plasma apparatus 200e, concentration of the electric field at the ends of the masking members 21e, 22e can be suppressed. Thirdly, therefore, in the case of etching by the plasma apparatus 200e, too, unevenness of etching is suppressed and etching is sufficiently performed at the end of the portion to be treated 10A.

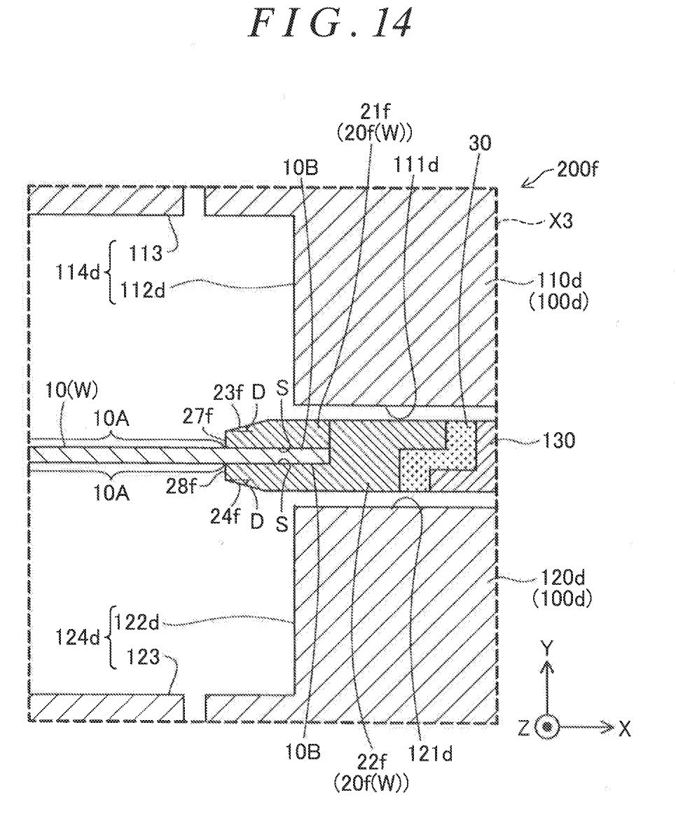

FIG. 14 is a schematic partial sectional view showing a part of a configuration of a plasma apparatus 200f in Modified Example 1 of the third embodiment. FIG. 14 shows a part X3 corresponding to the part X2 of FIG. 11. The plasma apparatus 200f of this modified example is different from the plasma apparatus 200e of the third embodiment mainly in that inclined surfaces 23f, 24f of a masking member 20f (21f, 22f) are not directly in contact with the ends of the portions to be treated 10A. In this modified example, the inclined surface 23f is connected to a surface 27f that is in contact with the end of the portion to be treated 10A on the upper surface side of the work piece W. Similarly, the inclined surface 24f is connected to a surface 28f that is in contact with the end of the portion to be treated 10A on the lower surface side of the work piece W. Description of the rest of the configuration of the plasma apparatus 200f of this modified example, which is the same as in the plasma apparatus 200e of the third embodiment, will be omitted.

As the plasma apparatus 200f has the inclined surfaces 23f, 24f, a decrease in film formation density or etching density at the end of the portion to be treated 10A can be prevented in the plasma apparatus 200f as in the third embodiment.

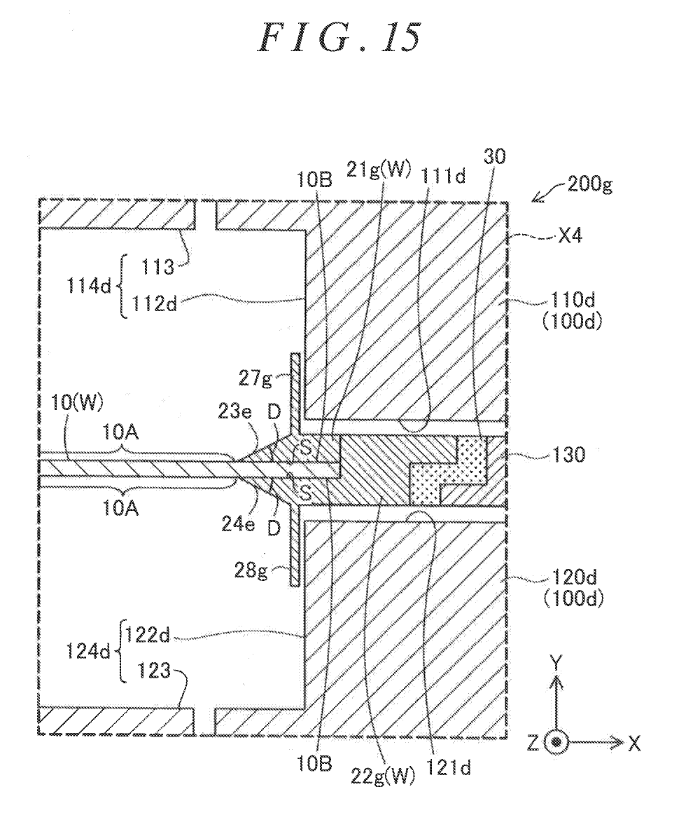

FIG. 15 is a schematic partial sectional view showing a part of a configuration of a plasma apparatus 200g in Modified Example 2 of the third embodiment. FIG. 15 shows a part X4 corresponding to the part X2 of FIG. 11. The plasma apparatus 200g of this modified example is different from the plasma apparatus 200e of the third embodiment in that an upper masking member 21g has a plate 27g in an area close to the side part 112d of the first casing 110d while a lower masking member 22g has a plate 28g in an area close to the side part 122d of the second casing 120d. The plates 27g, 28g are about 2.0 mm thick along the X-axis and about 20 to 30 mm long along the Y-axis, and distances along the X-axis between the side part 112d and the plate 27g and between the side part 122d and the plate 28g are about 1.0 mm. The plate 27g prevents contaminants resulting from film formation on the work piece from adhering to the side part 112d. Similarly, the plate 28g prevents contaminants resulting from film formation on the work piece from adhering to the side part 122d.

As the plasma apparatus 200g has the inclined surfaces 23e, 24e, a decrease in film formation density or etching density at the end of the portion to be treated 10A can be prevented in the plasma apparatus 200g as in the third embodiment. Moreover, adhesion of contaminants to the side parts 112d, 122d of the vacuum chamber 100d can be prevented. Alternatively, only one of the upper masking member 21g and the lower masking member 22g may be provided with the plate 27g or the plate 28g.

In the third embodiment, the masking member 20e (21e, 22e) has the inclined surfaces 23e, 24e. Alternatively, either the upper masking member 21e or the lower masking member 22e may have the inclined surface.

The same modifications as shown in Modified Examples 1 to 8, 10 and 11 of the first embodiment can be made to the plasma apparatus 200g of the third embodiment. The same modifications as shown in the modified examples of the second embodiment can also be made to the plasma apparatus 200g.

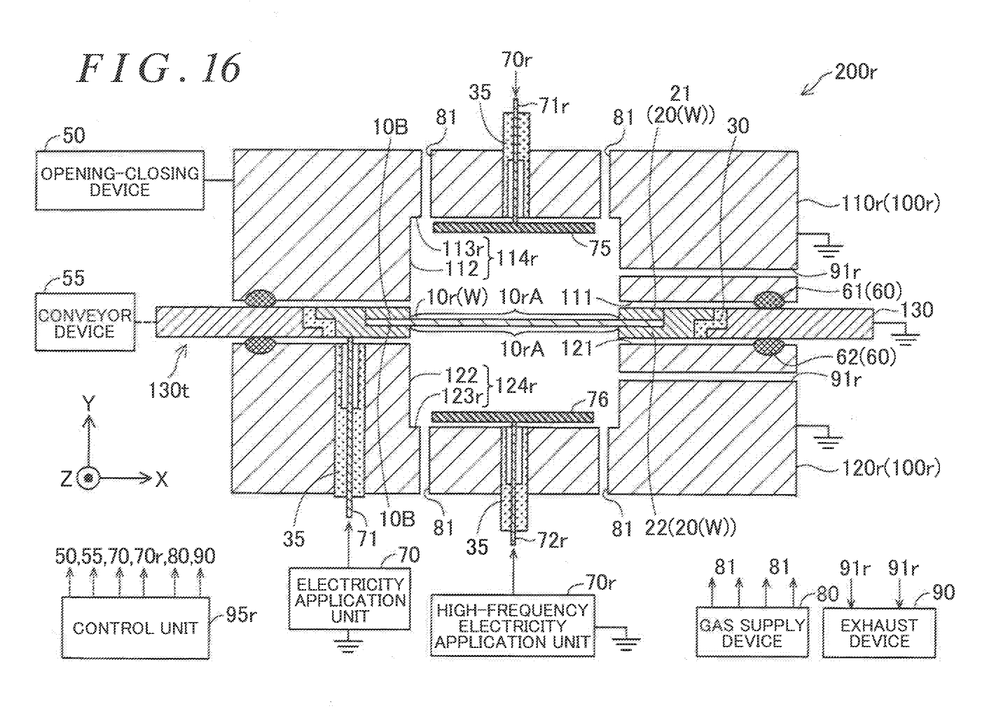

FIG. 16 is a view showing a plasma apparatus 200r in a fourth embodiment. The plasma apparatus 200r is an apparatus that can perform a plasma treatment on portions to be treated 10rA of the work piece W using electricity (direct-current (DC) electricity) applied by the electricity application unit 70 and electricity (radio-frequency (RF) electricity) applied by a high-frequency electricity application unit 70r. For this purpose, the plasma apparatus 200r includes a first electrode 75, a second electrode 76, and the high-frequency electricity application unit 70r. The first electrode 75 is disposed inside a first recess 114r, on a side closer to a bottom part 113r. The second electrode 76 is disposed inside a second recess 124r, on a side closer to a bottom part 123r. The high-frequency electricity application unit 70r applies electricity to the first electrode 75 and the second electrode 76 under control by a control unit 95r. Moreover, the high-frequency electricity application unit 70r can differentiate the level of high-frequency electricity applied to the first electrode 75 and the level of high-frequency electricity applied to the second electrode 76 from each other. In this embodiment, a first casing 110r includes an electricity introduction part 71r through which high-frequency electricity is applied to the first electrode 75, and an exhaust port 91r through which a gas is exhausted form a vacuum chamber 100r. A second casing 120r includes an electricity introduction part 72r through which high-frequency electricity is applied to the second electrode 76, and an exhaust port 91r through which a gas is exhausted from the vacuum chamber 100r. The electricity introduction part 71r and the first casing 110r, as well as the electricity introduction part 72r and the second casing 120r, are electrically insulated from each other by the insulating member 35. In this embodiment, a distance between the first electrode 75 and the first casing 110r and a distance between the second electrode 76 and the second easing 120r are shorter than the distance of the sheath. Accordingly, plasma is not generated between the first electrode 75 and the first casing 110r and between the second electrode 76 and the second casing 120r.

In this embodiment, the portion of the work piece. W located inside the first recess 114r and the second recess 124r is not provided with a hole penetrating the work piece W between the upper surface side and the lower surface side. Thus, in a state where the vacuum chamber 100r is closed, the work piece W separates the space inside the first recess 114r and the space inside the second recess 124r from each other (defines the border between these spaces). Accordingly, these spaces are electrically insulated from each other. This means that plasma generated inside the first recess 114r and plasma generated inside the second recess 124r are separated from each other by the work piece W. Description of the rest of the configuration of the plasma apparatus 200r of this embodiment, which is the same as in the plasma apparatus 200 of the first embodiment, will be omitted.

In a plasma treatment performed with the plasma apparatus 200r of this embodiment, electricity is applied to the work piece W in the step of applying electricity (step S50 in FIG. 4) of the plasma treatment method of the first embodiment (FIG. 4), and in addition, high-frequency electricity is applied to the first electrode 75 and the second electrode 76 by the high-frequency electricity application unit 70r. Description of the rest of the plasma treatment method of this embodiment, which is the same as in the first embodiment, will be omitted.

According to the plasma apparatus 200r of this embodiment, the space inside the first recess 114r and the space inside the second recess 124r are separated from each other by the work piece W, and these spaces are electrically insulated from each other. Thus, phase interference between high frequency applied to the first electrode 75 and high frequency applied to the second electrode 76 is prevented. As phase interference between high frequency applied to the first electrode 75 and high frequency applied to the second electrode 76 is prevented, electricity applied can be efficiently used to form a film on or etch the portion to be treated 10rA of the work piece W. Thus, it is possible to enhance the film formation density or the etching density in the portion to be treated 10rA by increasing the plasma density inside the first recess 114r and the second recess 124r. The film thickness can be increased in the case of forming a film on the portion to be treated 10rA by the plasma apparatus 200r, and the amount of etching in the portion to be treated 10rA can be increased in the case of etching the portions to be treated 10rA by the plasma apparatus 200r.

According to the plasma apparatus 200r of this embodiment, the space inside the first recess 114r and the space inside the second recess 124r are separated from each other by the work piece W, and the high-frequency electricity application unit 70r can differentiate the level of high-frequency electricity applied to the first electrode 75 and the level of high-frequency electricity applied to the second electrode 76 from each other. Thus, the film formation density or the etching density and the film thickness or the amount of etching can be differentiated between the portion to be treated 10rA on the upper surface side and the portion to be treated 10rA on the lower surface side. For example, in a case where an object to be treated 10r is a separator used for a fuel cell, and a cooling water channel is formed in the portion to be treated 10rA on the upper surface side and a fuel gas channel is formed in the portion to be treated 10rA on the lower surface side, it is preferable that the film formation density at least on the lower surface side be enhanced to enhance the fuel cell performance. According to the plasma apparatus 200r of this embodiment, it is possible to enhance the film formation density only on the lower surface side by raising the level of electricity applied to the second electrode 76 while keeping the level of electricity applied to the first electrode 75 as is. Thus, electricity consumption can be reduced when enhancing the film formation density or the etching density only on one side of the object to be treated 10r.

The present inventors formed films on the object to be treated 10r, with the level of electricity applied differentiated between the first electrode 75 and the second electrode 76. In this case, the pressure inside the vacuum chamber 100r was 30 Pa; the gas supplied into the vacuum chamber 100r was a pyridine gas; and the electricity applied to the work piece W by the electricity application unit 70 was −2500V. As a result, we confirmed that a 50 nm thick film and an 80 nm thick film were respectively formed on the portion to be treated 10rA on the upper surface side and on the portion to be treated 10rA on the lower surface side by applying −100 W electricity at 13.56 MHz to the first electrode 75 and applying −1000 W electricity at 13.56 MHz to the second electrode 76 by the high-frequency electricity application unit 70r. After film formation, the present inventors observed the portions to be treated 10rA on the upper surface side and the lower surface side with a field emission-scanning electron microscope (FE-SEM), and confirmed that a denser film was formed on the lower surface side than the upper surface side.

As the configuration of the plasma apparatus 200r of this embodiment is similar to that of the first embodiment, abnormal electric discharge can also be suppressed in the plasma apparatus 200r as in the first embodiment.

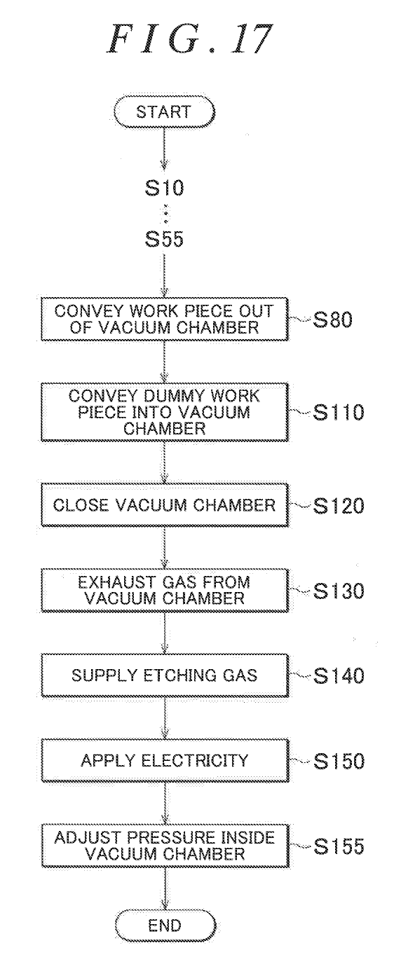

FIG. 17 is a flowchart showing a plasma treatment method in a modified example of the fourth embodiment. The plasma treatment method of this modified example includes a step of etching (or cleaning) inside the vacuum chamber 100r after film formation by the plasma apparatus 200r (step S10 to step S55 in FIG. 4). In this modified example, first, the work piece W is conveyed out of the vacuum chamber 100r (step S80) upon completion of film formation.

Next, a dummy work piece is conveyed into the vacuum chamber 100r (step S110). In step S110, for example, a dummy work piece, in place of the work piece W is conveyed into the vacuum chamber 100r. The dummy work piece is a metal plate that separates the space inside the first recess 114r and the space inside the second recess 124r from each other. In step S110, the pallet 130 loaded with the dummy work piece is conveyed into the vacuum chamber 100r. The conveyed pallet 130 is disposed on the second casing 120r through the seal member 62. Next, the vacuum chamber 100r is closed (step S120), and a gas is exhausted from the vacuum chamber 100r through the exhaust ports 91r by the exhaust device 90 (step S130).

When the gas has been exhausted from the vacuum chamber 100r, an etching gas is supplied into the vacuum chamber 100r (step S140). In step S140, for example, an argon gas, hydrogen gas, or nitrogen gas is supplied into the vacuum chamber 100r through the supply ports 81 by the gas supply device 80.

Next, electricity is applied to the work piece W by the electricity application unit 70 and electricity is applied to the first electrode 75 and the second electrode 76 by the high-frequency electricity application unit 70r (step S150). For example, the electricity application unit 70 applies −2500V electricity to the work piece W, and the high-frequency electricity application unit 70r applies −1000 W high-frequency electricity at 1156 MHz to the first electrode 75 and the second electrode 76. Thus, foreign substances having accumulated in the first recess 114r and the second recess 124r as a result of film formation are cleaned off (or etched).

When application of electricity and supply of gas are stopped and cleaning of the plasma apparatus 200r are completed, the pressure inside the vacuum chamber 100r is adjusted to open the vacuum chamber 100r (step S155). When the inside of the vacuum chamber 100r has been thus cleaned, the method is performed again from step S10 to form a film on the work piece W.

According to this modified example, the inside of the vacuum chamber 100r is cleaned after film formation, so that foreign substances having accumulated inside the vacuum chamber 100r can be removed. Thus, the film formation density or the etching density and the film thickness or the amount of etching in the work piece W that is conveyed into the vacuum chamber 100r after cleaning can be increased.

As the first recess 114r and the second recess 124r can be cleaned with the level of electricity applied to the first electrode 75 and the level of electricity applied to the second electrode 76 differentiated from each other, the first recess 114r and the second recess 124r can be cleaned appropriately according to the degree of accumulation of foreign substances. Moreover, electricity consumed for cleaning can be reduced in a case where foreign substances have accumulated in the first recess 114r and the second recess 124r to different degrees.

The same modifications as shown in Modified Examples 1, 2, 4 to 7 and 9 to 11 of the first embodiment can be made to the plasma apparatus 200r of the fourth embodiment. The same modifications as shown in the second embodiment and the modified examples of the second embodiment can also be made to the plasma apparatus 200r. Moreover, the same modifications as shown in the third embodiment and the modified examples of the third embodiment can also be made to the plasma apparatus 200r.

While the object to be treated 10 is a separator in the various embodiments described above, the object to be treated 10 may be any conductive member. While a carbon-based thin film is formed by the plasma apparatuses 200 to 200r in the above embodiments, in the case of film formation, a thin film of any other conductive element, such as gold (Au), platinum (Pt), tantalum (Ta), or silicon (Si), may be formed.

In the above embodiments, the first casings 110, 110b, 110d, 110m, 110r and the corresponding second casings 120, 120h, 120d, 120m, 120r may be swapped with each other.

The present disclosure is not limited to the above embodiments and modified examples but can be realized in various other configurations within the scope of the gist of the disclosure. For example, the technical characteristics of the embodiments and the modified examples corresponding to the technical characteristics of the configurations described in Summary can be appropriately replaced or combined, to solve a part or all of the problems described above or to achieve a part or all of the effects described above. Among the components in the above embodiments and modified examples, those components that are not described in the independent claim are additional components and can be omitted as appropriate.

What is claimed is:

1. A plasma apparatus configured to form a film on or etch a portion of a work piece by a plasma chemical vapor deposition method, the plasma apparatus comprising:
a vacuum chamber including a first casing that has a first recess and a first flat part disposed around the first recess, and a second casing that is disposed opposite to the first casing;
an insulating member that is disposed between the first flat part of the first casing and the second casing, and is configured to come in contact with the work piece in a state where a portion to be treated of the work piece faces a space inside the first recess and the work piece is separated from the first flat part; and
an electricity application unit that is configured to apply electricity to the work piece, wherein
a distance between the first flat part and a contact point between the work piece and the insulating member is shorter than a distance between the work piece and a bottom part of the first recess.

2. The plasma apparatus according to claim 1, wherein
a distance along the first flat part from a junction between the first recess and the first flat part to the contact point is larger than zero.

3. The plasma apparatus according to claim 1, wherein the distance between the first flat part and the contact point is shorter than a distance of a sheath formed between the work piece and the first flat part.

4. The plasma apparatus according to claim 1, wherein the distance between the first flat part and the contact point is 2.0 mm or less.

5. The plasma apparatus according to claim 1, wherein
the work piece includes an object to be treated, and a masking member covering a portion not to be treated of the object to be treated, and
a junction between the first recess and the first flat part is located so as to he separated from an end of the portion to be treated toward the insulating member.

6. The plasma apparatus according to claim 5, wherein an end of the masking member on a side closer to the portion to be treated has an inclined surface inclined toward the first recess.

7. The plasma apparatus according to claim 6, wherein an angle formed between the inclined surface and a contact surface of the masking member is 30° or less, the contact surface is configured to contact with the object to be treated.

8. The plasma apparatus according to claim 1, further comprising:
a first electrode disposed inside the first recess;
a second electrode disposed inside a second recess; and
a high-frequency electricity application unit that is configured to apply high-frequency electricity to the first electrode and the second electrode, wherein
the second casing has the second recess and a second flat part disposed around the second recess, and
the work piece is configured to separate a space inside the first recess and a space inside the second recess from each other.
